(19) United States
(12) Patent Application Publication
(10) Pub. No.: US 2010/0193461 A1
(43) Pub. Date: Aug. 5, 2010

(54) PLASMA-DEPOSITED BARRIER COATING INCLUDING AT LEAST THREE LAYERS, METHOD FOR OBTAINING ONE SUCH COATING AND CONTAINER COATED WITH SAME

(75) Inventors: Naima Boutroy, Octeville-Sur-Mer (FR); Nasser Beldi, Octeville-Sur-Mer (FR)

Correspondence Address: SUGHRUE MION, PLLC, 2100 PENNSYLVANIA AVENUE, N.W., SUITE 800, WASHINGTON, DC, 20037, US

(73) Assignee: SIDEL PARTICIPATIONS, Octeville-Sur-Mer (FR)

(21) Appl. No.: 12/667,814

(22) PCT Filed: Jul. 3, 2008
(86) PCT No.: PCT/FR08/51239

§ 371 Date: Jan. 5, 2010

(30) Foreign Application Priority Data
Jul. 6, 2007 (FR) 07 04899

(51) Int. Cl. B65D 23/02; C23C 16/513; B32B 17/06; B32B 1/02; B32B 7/02; B65D 90/00

(52) U.S. Cl. 215/12.2; 427/579; 428/428; 428/36.6; 428/216; 206/524.3

(57) ABSTRACT

The invention relates to a method that uses a low-pressure plasma to deposit a barrier coating on a substrate, of the type in which the plasma is obtained by partial ionisation, under the influence of an electromagnetic field, of a reaction fluid injected at low pressure into a treatment zone. The method includes: at least a step in which a first layer, obtained in the plasma state bearing a mixture containing at least one organosilicon compound and one other compound, is deposited on the substrate; a step in which a second layer, essentially consisting of silicon oxide having formula SiOx, is deposited on the first layer; and at least a step in which a third layer, obtained in the plasma state bearing a mixture containing at least one organosilicon compound and one other compound, is deposited on the second layer, said aforementioned other compounds both taking the form of nitrogen compounds, such as nitrogen gas.

The field of application of the present invention is thin layer barrier coatings deposited by using a low-pressure plasma, i.e. at a pressure below atmospheric pressure, and more specifically at a pressure of the order of 5×10⁻⁴ bar. Conventionally, such coatings are obtained by injecting a reaction fluid, generally in a gaseous state, at low pressure into a treatment zone. An electromagnetic field is formed in the treatment zone in order to bring this fluid to the plasma state, i.e., to cause its at least partial ionisation. The particles resulting from this ionisation can then be deposited on the walls of the object placed in the treatment zone.

Low-pressure plasma or cold plasma deposition can be used to deposit thin layers on plastic objects, for example films or containers, in particular with the aim of reducing their permeability to gases such as oxygen and carbon dioxide.

It is thus possible to use such a technology to coat plastic bottles with a barrier material, in particular made from a thermoplastic material, intended for the packaging of products sensitive to oxygen, such as beer or fruit juice, or carbonated products such as soft drinks.

A device making it possible to coat the inner or outer surface of a plastic bottle with a barrier coating is for example described in document WO99/49991.

A method is also known from document FR 2 812 568 in the name of the Applicant using a low-pressure plasma to deposit a barrier coating on a substrate to be treated, of the type in which the plasma is obtained by partial ionisation, under the influence of an electromagnetic field, of a reaction fluid injected at low pressure into a treatment zone, the method comprising at least one step consisting of depositing on the substrate an interface layer that is obtained by bringing to the plasma state a mixture comprising at least one organosilicon compound and one nitrogenous compound, and a step consisting of depositing a barrier layer consisting essentially of a silicon oxide with the formula SiOx on the interface layer.

However, although the barrier coating obtained according to the method described in document FR 2 812 568 is satisfactory, it would be in particular useful to improve the barrier properties of the plastic container obtained in order to thus increase the storage life of the drinks packaged in these containers while retaining their nutritional qualities.

In addition, a method is known from document EP 1 630 250 A1 using a low-pressure plasma to deposit a barrier coating vis-à-vis gases on a thermoplastic substrate, in which the plasma is obtained by partial ionisation, under the influence of an electromagnetic field, of a reaction fluid injected at low pressure into a treatment zone.

A first layer of an organosilicon polymer, which is flexible and adheres to the substrate (adhesion layer or interface layer), is formed on the surface of a substrate such as a substrate made from a thermoplastic material, in a vacuum pre-evaporation step. Then, a second layer of silicon oxide SiOx, which has gas barrier properties, is formed on the adhesion layer in a main vacuum evaporation step. Finally, a third, outer, layer is formed on the silicon oxide layer in a vacuum post-evaporation step, this third layer having a composition close to that of the aforementioned second layer and having hydrophobic properties improving the water vapour barrier properties.

According to this known method, the deposition of three layers is carried out continuously, with the supply to the reaction chamber of at least one organometallic compound, in particular an organosilicon compound, with a constant flow rate, and an oxidizing gas (which can be oxygen) with a flow rate modified over time in relation to the characteristics of the layer to be formed, in such a way that the composition (Si, O, C) of the coating varies depending on the layers.

A coating constituted according to this document has a gas barrier function, in particular to oxygen and carbon dioxide, which is conferred on it by the second layer supported by the first adhesion layer, whilst it also has a water vapour barrier function conferred on it by the third outer layer.

However, the gas barrier function is not affected by the presence of the third outer layer, and more specifically, the gas barrier function is not improved or increased in efficiency due to the presence of the third outer layer.

A gas barrier effect coating made up of three layers, including a first adhesion layer and a second silica SiOx layer as disclosed above is also known from the aforementioned document FR 2 812 568. However, the third, outer, layer is made up of hydrogenated amorphous carbon deposited by low-pressure plasma with too small a thickness for this third layer to have any barrier effect whatsoever. It is therefore solely a protective layer, allowing for a reduction in the degradation of the barrier properties of the coating in the presence of deformations, and the barrier effect is conferred solely by the second layer.

Finally, document WO 01/94448 A1 describes a barrier effect coating formed, using a plasma, on a thermoplastic substrate such as PET, which coating comprises a first layer with the formula SiOxCyHz that is deposited in contact with the substrate as a sub-layer for a second layer of SiOx having a barrier effect; an additional layer is formed on the second layer (Examples 1 and 2 in said document); the process unfolds by treating an organosilicon compound TMDSO alone at first, in order to form the first layer, and then with an oxygen supply and with appropriate adjustment of the TMDSO and oxygen flow rates to form the second layer, then the third layer; a clear, colourless coating is obtained. Example 8a in this document sets out a continuous formation process of the three layers, keeping a constant TMDS flow rate and modifying the oxygen flow rate (zero flow rate for the first layer, given flow rate for the second layer, flow rate increased tenfold for the third layer) and adjusting the application time of the microwave power (2 seconds for the first layer, 5 seconds for the second layer, 4 seconds for the third layer); the clear, colourless coating obtained has barrier properties similar to those obtained in Example 2. The method known according to this document is carried out in particular by adjustment of the oxygen flow rate, and the clearly established aim is to find a clear, colourless coating that does not modify the colour of the substrate, and not an improvement in the barrier effect.

In light of the state of the art that has just been set out, two aspirations emerge, which can seem at least partly a priori irreconcilable, or even opposing. On the one hand, packagers of sensitive liquids wish to be able to avail themselves of containers made from a thermoplastic material that have improved barrier characteristics allowing for said sensitive liquids to be stored for longer with reduced loss of their qualities. Such an aim could doubtless be achieved with barrier effect coatings strengthened with thicker and/or more barrier layers (multiple layers). On the other hand, still at the request of packagers, it is desirable to simplify and speed up the barrier coating deposition process as much as possible in order to reduce the cost price and increase the production rate. These specific aims are completely incompatible with the implementation of thicker and/or more layers.

It would also be in particular useful, relative to the methods according to the prior art, to produce a method of plasma deposition of inner barrier layers that is easy to implement from an industrial point of view and does not require excessively accurate adjustment.

In this context, the invention proposes means (method and coating) that allow for the two aforementioned a priori irreconcilable requirements to be satisfied.

To this end, according to a first of its aspects, the present invention relates to a method implementing a low-pressure plasma to deposit a barrier coating vis-à-vis gases on a thermoplastic substrate, in which the plasma is obtained by partial ionisation, under the influence of an electromagnetic field, of a reaction fluid injected at low pressure into a treatment zone, such method comprising:
at least a first step consisting of depositing, on the thermoplastic substrate, a first layer, or adhesion layer, which is obtained by bringing to the plasma state a mixture comprising at least one organosilicon compound and another compound,
at least a second step consisting of depositing, on said first layer, a second layer, or barrier effect layer, which is obtained by bringing to the plasma state a compound leading essentially to a silicon oxide with the formula SiOx, which second layer has a barrier effect vis-à-vis gases, and
at least a third step consisting of depositing, on said second layer, a third layer, which is obtained by bringing to the plasma state a mixture comprising at least one organosilicon compound and another compound,
the mixtures used for the formation of the first and third layers having at least relatively similar compositions,
   characterised in that said other compounds are both nitrogenous compounds.

Of course, nitrogen is already present in the reactions carried out according to the methods known from the aforementioned documents. However, in these cases nitrogen is used as a carrier gas (neutral gas in the context of these methods) and/or is present in a compound of the NOx type, which is used as an oxidant. In any case, the reactions are carried out with an oxidant (either gaseous oxygen or oxygen released by an oxidizing compound such as NOx). Due to its high reactivity, only oxygen acts effectively in the reactions disclosed in the aforementioned documents, while nitrogen, due to its lesser reactivity, does not react and is not present in the compositions of the layers formed. Thus, the first and third layers of the coatings of the prior art correspond to the formula SiOx′Cy′Hz′, whereas the first and third layers of the coating according to the invention correspond to the formula SiOxCyHzNu, where x, y, z and u can have the values given below.

The Applicant was therefore surprised to find that, although the first and third layers do not individually have any barrier effect vis-à-vis gases, the first, second and third layers as a whole have a barrier effect vis-à-vis gases that is greater than the effect provided by the first and second layers alone.

In a preferred embodiment, said mixtures used for the formation of the first and third layers respectively have identical compositions and comprise the same nitrogenous compound.

In a simple and therefore preferred embodiment, the nitrogenous compound is nitrogen gas.

Advantageously, the step consisting of depositing a second layer consisting essentially of a silicon oxide with the formula SiOx is obtained by bringing to the plasma state a mixture comprising at least one organosilicon compound, a nitrogenous compound and oxygen.

Advantageously, the organosilicon compound is an organosiloxane, preferably hexamethyldisiloxane, trimethyldisiloxane or trimethylsilane.

Advantageously, in order to reduce the total time for the implementation of the method according to the invention, the steps are linked continuously in such a way that, in the treatment zone, the reaction fluid remains in the plasma state during the transitions between the different steps.

Advantageously, for a treatment zone with a volume of 500 mL, the hexamethyldisiloxane injection rate is between 4 and 12 sccm, and is preferably 5 sccm, the nitrogen gas injection rate is between 10 and 100 sccm, and is preferably 30 sccm, the dioxygen injection rate is between 40 and 120 sccm, the microwave power applied is between 200 and 500 W, and is preferably 350 W.

In order to allow for the highest production rate possible, the deposition time of the first layer is between 0.2 and 2 seconds, in that the deposition time of the second layer is between 1 and 4 seconds and in that the deposition time of the third layer is between 0.2 and 2 seconds, the total time of the method being between 2.4 and 4 seconds.

According to a second of its aspects, the present invention also relates to a barrier coating deposited on a thermoplastic substrate by low-pressure plasma, comprising:
a first layer, or adhesion layer, deposited on the substrate, constituted by a compound comprising at least silicon, carbon, oxygen and hydrogen,
a second layer, or barrier effect layer, deposited on said first layer, composed essentially of a silicon oxide with the formula SiOx, and
a third layer deposited on said second layer, constituted by a compound comprising at least silicon, carbon, oxygen and hydrogen,
the first and third layers having substantially similar chemical compositions, characterised in that said compounds constituting the first and third layers both also comprise nitrogen,
   as a result of which, although the first and third layers do not individually have any barrier effect vis-à-vis gases, the first, second and third layers as a whole have a barrier effect vis-à-vis gases that is greater than the effect provided by the first and second layers alone.

Advantageously, the thickness of the first and third layers is less than 20 nm, and is preferably approximately 4 nm.

Advantageously, the first layer and the third layer have substantially the same chemical composition.

According to an advantageous embodiment of the coating according to the invention, the second layer consists essentially of a silicon oxide with the formula SiOx, where x is between 1.8 and 2.1.

Advantageously, the first layer and/or the third layer has a chemical composition with the formula SiOxCyHzNu, the value of x being between 1 and 1.5, and preferably 1.25, the value of y being between 0.5 and 2, and preferably 1.5, the value of z being between 0.5 and 2, and preferably 0.85, the value of u being between 0.1 and 1, and preferably 0.5.

Additionally, the coating according to the invention comprises a fourth layer, deposited on the third layer, composed essentially of a silicon oxide with the formula SiOx, together with a fifth layer, deposited on the fourth layer, composed essentially of silicon, carbon, oxygen, nitrogen and hydrogen.

According to a third of its aspects, the present invention also relates to a container made from a polymer material, characterised in that it is covered, on at least one of its surfaces, with a barrier coating as indicated above.

Advantageously, the container is coated with a barrier coating on its inner surface.

Advantageously, the container is a polyethylene terephthalate bottle.

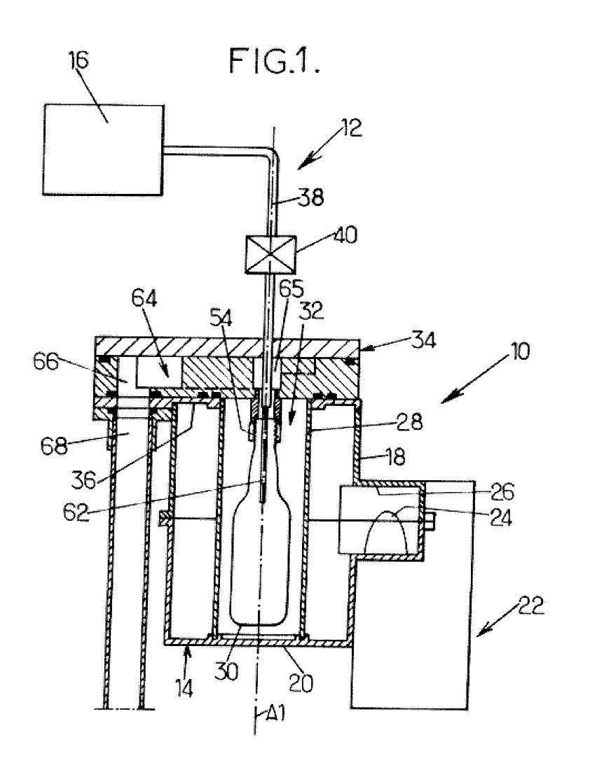

The present invention will now be described using a purely illustrative example that in no way limits the scope of the invention and on the basis of the following illustration, in which FIG. 1 is a diagrammatic axial cross-sectional view of a possible embodiment of a treatment station appropriate to the implementation of the method according to the invention.

In the following, the invention is described in the context of the treatment of plastic containers, and more specifically in the form of a device and a method making it possible to coat the inner surface of a plastic container such as a bottle.

The treatment station 10 can for example form part of a rotary machine comprising a carousel rotating continuously around a vertical axis.

The treatment station 10 comprises a chamber 14 made from an electrically conducting material and formed by a tubular cylindrical wall 18 with a vertical axis A1. The chamber 14 is closed at its lower end by a lower base wall 20.

Outside the chamber 14 and fixed to it is a housing 22 that comprises means (not shown) of creating an electromagnetic field inside the chamber 14 capable of generating a plasma and which are in particular capable of generating electromagnetic radiation in the UHF domain, i.e., in the microwave domain. In this case, the housing 22 can therefore contain a magnetron the antenna 24 of which opens out into a wave guide 26, for example in the form of a tunnel with a rectangular cross-section that opens out directly inside the chamber 14, through the side wall 18. However, the invention could also be implemented in the context of a device equipped with a radio frequency type radiation source, and/or the source could also be arranged differently, for example at the lower axial end of the chamber 14.

Inside the chamber 14 is a tube 28 with an axis A1 that is made from a transparent material, for example quartz, for the electromagnetic waves introduced into the chamber 14 via the wave guide 26. This tube 28 is intended to hold a container to be treated and defines a cavity 32 in which negative pressure will be created once the container is inside the chamber.

The chamber 14 is partly closed at its upper end by an upper wall 36 that is provided with a central opening in such a way that the tube 28 is completely open upwards to allow for the container 30 to be inserted into the cavity 32.

To close the chamber 14 and the cavity 32, the treatment station 10 comprises a cover 34 that is axially mobile between an upper position (not shown) and a sealed lower closed position shown in FIG. 1, in which the cover 34 rests in a sealed manner against the upper surface of the upper wall 36 of the chamber 14.

The cover 34 has means 54 of supporting the container of a type known per se, in the form of a gripper cup that engages or clips around the neck, preferably under the collar of the container (the containers preferably being bottles made from a thermoplastic material, for example polyethylene terephthalate (PET) and comprising a collar protruding radially at the base of their neck).

The internal treatment of the container requires that it be possible to control both the pressure and the composition of the gases present inside the container. To this end, it must be possible to connect the inside of the container to a source of negative pressure and to a device for supplying the reaction fluid 12. The latter therefore comprises a source 16 of reaction fluid connected by a pipe 38 to an injector 62 that is arranged along the axis A1 and is mobile relative to the cover 34 between an upper retracted position (not shown) and a lower position in which the injector 62 is plunged inside the container 30, through the cover 34. A controlled valve 40 is placed in the pipe 38 between the fluid source 16 and the injector 62.

So that the gas injected by the injector 62 can be ionised and form a plasma under the influence of the electromagnetic field created in the chamber, it is necessary for the pressure in the container to be lower than atmospheric pressure, for example of the order of 5×10⁻⁴ bar. To connect the inside of the container with a source of negative pressure (for example a pump), the cover 34 comprises an inner channel 64, a main termination of which opens into the lower surface of the cover, more specifically in the centre of the bearing surface against which the neck of the bottle 30 is pressed.

In the example shown, the inner channel 64 of the cover 24 comprises a joining end 66 and the vacuum circuit of the machine comprises a fixed end 68 that is arranged in such a way that the two ends 66, 68 are facing each other when the cover is in the closed position.

The device that has just been described can therefore operate as follows. Once the container has been loaded on the gripper cup 54, the cover is lowered to its closed position. At the same time, the injector is lowered through the main termination 65 of the channel 64, but without closing it off. When the cover is in the closed position, it is possible to evacuate the air contained in the cavity 32, which is connected to the vacuum circuit by means of the inner channel 64 of the cover 34.

Initially, the valve is controlled so that it is open, so that the pressure drops in the cavity 32 both outside and inside the container. When the vacuum level outside the container has reached a sufficient level, the system controls the closing of the valve. It is then possible to continue pumping solely inside the container 30.

Once the treatment pressure has been reached, the treatment can start according to the method of the invention.

Initially, a mixture of an organosilicon compound, for example organosiloxane, and preferably hexamethyldisiloxane (HMDSO) and a nitrogenous compound, preferably nitrogen gas (N₂), is injected into the treatment zone for a time T1, preferably less than one second.

As organosiloxanes, such as HMDSO, trimethyldisiloxane, trimethylsilane and tetramethylsiloxane (TMDSO), are generally liquid at ambient temperature (generally around 20-25° C.), and in order to inject them into the treatment zone in a gaseous form, either a carrier gas is used, which combines with vapours of the organosiloxane in a bubbler, or the operation is carried out at the saturation vapour pressure of the organosiloxane. Generally, the carrier gas is an inert gas such as helium or argon, although preferably nitrogen gas (N₂) is used as a carrier gas.

Microwaves are then applied for a time T2, which allows for the gaseous mixture injected to be brought to the plasma state, T2 corresponding to the time necessary to deposit a first layer on the substrate to be treated, namely a film or the inner surface of a container made from a thermoplastic material such as PET.

Preferably, in order to obtain the first layer on the substrate, for a treatment zone having a volume of 500 mL, the hexamethyldisiloxane injection rate is between 4 and 12 sccm (standard cubic centimetres per minute) and is preferably 5 sccm, the nitrogen gas (N₂) injection rate is between 10 and 100 sccm, and is preferably 30 sccm, and the microwave power applied is between 200 and 500 W, and is preferably 350 W. The deposition time of the first layer is between 0.2 and 2 seconds, which allows for a first layer to be obtained that is approximately 4 nm thick.

The first layer formed is thus composed of silicon Si atoms, carbon C atoms, oxygen O atoms, nitrogen N atoms and hydrogen H atoms and has a chemical composition with the formula SiOxCyHzNu, the value of x being between 1 and 1.5, and preferably 1.25, the value of y being between 0.5 and 2, and preferably 1.5, the value of z being between 0.5 and 2, and preferably 0.85, and the value of u being between 0.1 and 1, and preferably 0.5.

Preferably, the composition of the first layer is approximately 20% silicon atoms, approximately 25% oxygen atoms, approximately 30% carbon atoms, approximately 10% nitrogen atoms and approximately 15% hydrogen atoms.

It must be emphasised that the first layer formed in this way does not in itself have any gas barrier effect and that its function is to provide perfect adhesion between the thermoplastic substrate and the second layer, which is discussed below.

In order to form a second barrier effect layer on the first layer, a compound leading essentially to a silicon oxide of the SiOx type is brought to the plasma state. To this end, in addition to the mixture comprising at least one organosilicon compound and one nitrogenous compound, in particular a mixture respectively of HMDSO and N₂, a quantity of oxygen is injected into the treatment zone for a time T3.

Preferably, provision is made to inject nitrogen gas during the step of deposition of the second layer, although nitrogen is not necessary in order to obtain a layer of the SiOx type.

Microwaves are then applied for a time T4, which corresponds to the time necessary to form the second layer of an SiOx type. In fact, the oxygen, of which there is a considerable excess in the plasma when it is injected, causes the almost complete elimination of the carbon, nitrogen and hydrogen atoms that are provided either by the HMDSO or the nitrogen.

Preferably, in order to obtain the second barrier layer of an SiOx type, for a treatment zone with a volume of 500 mL, the hexamethyldisiloxane injection rate is between 4 and 12 sccm, and is preferably 5 sccm, the nitrogen gas injection rate is between 10 and 100 sccm, and is preferably 30 sccm, the dioxygen injection rate is between 40 and 120 sccm, the microwave power applied is between 200 and 500 W, and is preferably 350 W. The deposition time for the second layer is between 1 and 4 seconds. Advantageously, the HMDSO and N₂ flow rates are not therefore modified between the first layer formation step and the second barrier layer formation step, allowing for continuous formation of the different layers with no stoppage time between the different steps.

A material of the SiOx type is thus obtained, where x expresses the ratio of the quantity of oxygen to the quantity of silicon, which is generally between 1.5 and 2.2 depending on the operating conditions used, and is preferably between 1.8 and 2.1. Of course, impurities due to the method of obtaining the material can be incorporated into this layer in small quantities without significantly modifying its properties.

The second layer is essentially in the form of a silicon oxide of the SiOx type. It can thus be seen that the chemical composition of the second layer is constitued by approximately 30% silicon atoms, approximately 63% oxygen atoms, approximately 3% carbon atoms and approximately 4% hydrogen atoms.

At the end of the injection of oxygen O₂, a mixture of an organosilicon compound, in particular HMDSO, and a nitrogenous compound, in particular N₂, is then injected into the treatment zone and microwaves are applied for a time T5, which leads to the deposition of a third layer on the second barrier layer. The mixtures used for the formation of the first and third layers have relatively similar compositions, and preferably these mixtures have identical compositions.

Preferably, in order to obtain the third layer, for a treatment zone with a volume of 500 mL, the hexamethyldisiloxane injection rate is between 4 and 12 sccm, and is preferably 5 sccm, the nitrogen gas injection rate is between 10 and 100 sccm, and is preferably 30 sccm, the microwave power applied is between 200 and 500 W, and is preferably 350 W. The deposition time for the third layer is between 0.2 and 2 seconds. In this way, a third layer is obtained that is approximately 4 nm thick. Again, the same flow rates of HMDSO and N₂ are preferably injected into the treatment zone as during the first and second layer formation steps.

It must be emphasised that the third layer formed in this way is substantially identical to the aforementioned first layer and that, like the first layer, it does not in itself have any gas barrier effect.

The total time to carry out the deposition of the three layers according to the method of the invention is between 2.4 seconds and 4 seconds, which allows for production rates of coated containers of between 10,000 containers/hour and 30,000 containers/hour to be achieved.

Preferably, the deposition speeds for the first and third layers are between 6 and 12 nm/s, preferably around 9 nm/s, and the deposition speed for the second layer, of an SiOx type, is between 2 and 6 nm/s, and preferably around 4 nm/s.

The third layer formed in this way is made up of silicon Si atoms, carbon C atoms, oxygen O atoms, nitrogen N atoms and hydrogen H atoms. More specifically, preferably, the third layer has a chemical composition with the formula SiOxCyHzNu, the value of x being between 1 and 1.5, and preferably 1.25, the value of y being between 0.5 and 2, and preferably 1.5, the value of z being between 0.5 and 2, and preferably 0.85, and the value of u being between 0.1 and 1, and preferably 0.5. According to a preferred embodiment, the third layer contains approximately 20% silicon atoms, approximately 25% oxygen atoms, approximately 30% carbon atoms, approximately 10% nitrogen atoms and approximately 15% hydrogen atoms.

To summarise the preferred embodiment, the table below shows the atomic composition of the three layers forming the coating according to the invention.

| | % Si | % O | % C | % N | % H |
|---|---|---|---|---|---|
| 1^{st} layer | 20 | 25 | 30 | 10 | 15 |
| 2^{nd} layer | 30 | 63 | 3 | 0 | 4 |
| 3^{rd} layer | 20 | 25 | 30 | 10 | 15 |

Although, preferably, the first layer and the third layer are substantially identical and both have a thickness of less than 20 nm, and preferably 4 nm, it is also possible for the first layer to be different from the third layer in terms of chemical composition, although the first and third layers are always made up of silicon Si atoms, carbon C atoms, oxygen O atoms, nitrogen N atoms and hydrogen H atoms.

Furthermore, it must be noted that the different layers formed on the substrate, and more specifically the different layers formed inside the container, can comprise other elements (that is, elements other than Si, C, O, H and N for the first and third layers and Si and O for the second layer) in small or trace quantities, these other components originating from impurities contained in the reaction fluids used or simply impurities due to the presence of residual air remaining at the end of pumping.

After stopping the microwaves and stopping the injection of the gaseous mixture, the container is then returned to atmospheric pressure.

Preferably, the reaction source 16, as shown diagrammatically in FIG. 1, is constituted by a first gaseous source containing a mixture of an organosilicon compound, in particular HMDSO, and a nitrogenous compound, in particular nitrogen N₂, and a second gaseous source containing oxygen O₂.

The different steps for the implementation of the method according to the invention can be carried out in the form of completely separate steps or, conversely, in the form of several linked steps, without the plasma being extinguished between them.

The barrier coating obtained in this way performs in particular well with regard to the oxygen permeability rate. Thus, a standard 500 ml PET (polyethylene terephthalate) bottle on which no barrier layer has been deposited has a permeability rate of 0.04 cubic centimetres of oxygen entering the bottle per day.

After application of a three-layer coating according to the method of the invention, the permeability rate is 0.001 cubic centimetres of oxygen entering the bottle per day measured at 1 bar, i.e. an improvement by a factor of 40 of the oxygen permeability rate value compared with an uncoated PET container according to the prior art.

The method according to the invention thus allows for an improvement factor of the oxygen barrier for a container of at least 40.

In other words, the Applicant has found that, without however being able to explain it, surprisingly, although the first and third layers do not individually have any barrier effect vis-à-vis gases, the first, second and third layers forming the coating according to the invention as a whole have a gas barrier effect that is greater than the effect provided by the first and second layers of the prior coatings alone.

Moreover, it must be noted that in order to increase the barrier effect and impermeability to oxygen, it is possible to provide a fourth layer, deposited on the third layer, consisting essentially of a silicon oxide with the formula SiOx, as well as a fifth layer, deposited on the fourth layer, composed essentially of silicon, carbon, oxygen, nitrogen and hydrogen.

In this case, the fourth layer can have substantially the same chemical composition as the second layer and can be obtained under similar conditions of flow rate and gaseous mixture injected, whilst the fifth layer can have substantially the same chemical composition as the first and third layers and can be obtained under similar conditions of flow rate and gas mixture injected.

Generally, it is thus possible to envisage depositing alternating (2n+1) barrier layers on the substrate (and preferably on the inner surface of a bottle), n being an integer greater than or equal to 1, with the first, third, . . . , (2n+1)th layers consisting essentially of silicon, carbon, oxygen, nitrogen and hydrogen, whilst the second, fourth, . . . , (2n)th layers consist essentially of a silicon oxide with the formula SiOx.

The Applicant has thus found that by multiplying the number of interfaces of the SiOxCyHzNu/SiOx type, a very clear improvement in the barrier effect appears, whilst benefiting from better control over the deposition method, resulting in ease of implementation from an industrial point of view.

1. A method implementing a low-pressure plasma to deposit a barrier coating vis-à-vis gases on a thermoplastic substrate, in which said plasma is obtained by partial ionisation, under the influence of an electromagnetic field, of a reaction fluid injected at low pressure into a treatment zone, such method comprising:
at least a first step consisting of depositing, on said thermoplastic substrate, a first layer, named adhesion layer, which is obtained by bringing to a plasma state a mixture comprising at least one organosilicon compound and another compound,
at least a second step consisting of depositing, on said first layer, a second layer, named barrier effect layer, which is obtained by bringing to said plasma state a compound leading essentially to a silicon oxide with the formula SiOx, which second layer has a barrier effect vis-à-vis gases, and
at least a third step consisting of depositing, on said second layer, a third layer, which is obtained by bringing to said plasma state a mixture comprising at least one organosilicon compound and another compound,
said mixtures used for the formation of said first and third layers having at least relatively similar compositions,
wherein said other compounds are both nitrogenous compounds,
as a result of which, although said first and third layers do not individually have any barrier effect vis-à-vis gases, said first, second and third layers as a whole have a barrier effect vis-à-vis gases that is greater than the effect provided by said first and second layers alone.

2. The method according to claim 1, wherein said mixtures used for the formation of said first and third layers respectively have identical compositions and comprise a same nitrogenous compound.

3. The method according to claim 1, wherein said nitrogenous compound is nitrogen gas.

4. The method according to claim 1 wherein said step consisting of depositing a second layer composed essentially of a silicon oxide with the formula SiOx is obtained by bringing to said plasma state a mixture comprising at least one organosilicon compound, a nitrogenous compound and oxygen.

5. The method according to claim 1, wherein said organosilicon compound is an organosiloxane.

6. The method according to claim 1, wherein said at least first, at least second and at least third steps are linked continuously in such a way that, in said treatment zone, said reaction fluid remains in said plasma state during the transitions between said steps.

7. The method according to claim 3, wherein, for a treatment zone with a volume of 500 mL,
said organosilicon compound is hexamethyldisiloxane with an injection rate of between 4 and 12 sccm, preferably 5 sccm,
said nitrogen gas has an injection rate of between 10 and 100 sccm, preferably 30 sccm,
said oxygen has an injection rate of between 40 and 120 sccm, and
a microwave power applied is between 200 and 500 W.

8. The method according to claim 1, wherein a deposition time of said first layer is between 0.2 and 2 seconds, a deposition time of said second layer is between 1 and 4 seconds and a deposition time of said third layer is between 0.2 and 2 seconds, a total time of the method being between 2.4 and 4 seconds.

9. A barrier coating deposited on a thermoplastic substrate by low-pressure plasma, comprising:
a first layer, named adhesion layer, deposited on said substrate, constituted by a compound comprising at least silicon, carbon, oxygen and hydrogen,
a second layer, named barrier effect layer, deposited on said first layer, composed essentially of a silicon oxide with the formula SiOx, and
a third layer deposited on said second layer, constituted by a compound comprising at least silicon, carbon, oxygen and hydrogen,
said first and third layers having substantially similar chemical compositions,
wherein said compounds forming said first and third layers both also comprise nitrogen,
as a result of which, although said first and third layers do not individually have any barrier effect vis-à-vis gases, said first, second and third layers as a whole have a barrier effect vis-à-vis gases that is greater than the effect provided by said first and second layers alone.

10. The coating according to claim 9, wherein said first and third layers have a thickness which is less than 20 nm.

11. The coating according to claim 9, wherein said first layer and said third layer have substantially a same chemical composition.

12. The coating according to claim 9, wherein said second layer is essentially composed of a silicon oxide with the formula SiOx, where x is between 1.8 and 2.1.

13. The coating according to claim 9, wherein at least one of said first layer and the third layer has a chemical composition with the formula SiOxCyHzNu, the value of x being between 1 and 1.5, preferably 1.25, the value of y being between 0.5 and 2, preferably 1.5, the value of z being between 0.5 and 2, preferably 0.85, and the value of u being between 0.1 and 1, preferably 0.5.

14. The coating according to claim 9, further comprising a fourth layer, deposited on said third layer, composed essentially of a silicon oxide with the formula SiOx, together with a fifth layer, deposited on said fourth layer, composed essentially of silicon, carbon, oxygen, nitrogen and hydrogen.

15. A container made from a polymer material, which is covered, on at least one of its surfaces, with a barrier coating comprising:
a first layer, named adhesion layer, deposited on said substrate, constituted by a compound comprising at least silicon, carbon, oxygen and hydrogen,
a second layer, named barrier effect layer, deposited on said first layer, composed essentially of a silicon oxide with the formula SiOx, and
a third layer deposited on said second layer, constituted by a compound comprising at least silicon, carbon, oxygen and hydrogen,
said first and third layers having substantially similar chemical compositions,
wherein said compounds forming said first and third layers both also comprise nitrogen,
as a result of which, although said first and third layers do not individually have any barrier effect vis-à-vis gases, said first, second and third layers as a whole have a barrier effect vis-à-vis gases that is greater than the effect provided by said first and second layers alone.

16. The container according to claim 15, which is coated with a barrier coating on its inner surface.

17. The container according to claim 15, which is a bottle made of polyethylene terephthalate.

18. The method according to claim 5, wherein said organosiloxane is selected in the group comprising hexamethyldisiloxane, trimethyldisiloxane and trimethylsilane.

19. The method according to claim 7, wherein said microwave power is 350 W.

20. The coating according to claim 10, wherein said first and third layers have a thickness which is approximately 4 nm.
